(19) United States
(12) Patent Application Publication
(10) Pub. No.: US 2007/0111500 A1
(43) Pub. Date: May 17, 2007

(54) Method and apparatus for attaching solder balls to substrate

(76) Inventors: Marvin W. Cowens, Plano, TX (US); Arthur A. Bayot, Baguio City (PH); Jabeeh Areola, Baguio City (PH); Sergio Martinez, Allen, TX (US)

Correspondence Address: TEXAS INSTRUMENTS INCORPORATED, P O BOX 655474, M/S 3999, DALLAS, TX, 75265, US

(21) Appl. No.: 11/591,237

(22) Filed: Nov. 1, 2006

Related U.S. Application Data
(60) Provisional application No. 60/732,503, filed on Nov. 1, 2005.

(51) Int. Cl. H01L 21/44

(52) U.S. Cl. 438/612

(57) ABSTRACT

A method for attaching solder balls to solder pads on a circuit board, comprising distributing an approximately uniform flat layer of solder paste with distributed solder particles on top of a flat plate employing a squeegee, picking up the solder balls from a solder ball bin utilizing a vacuum tool, dipping the solder balls into the solder paste, lifting the solder balls out of the solder paste, placing the solder balls with the solder paste proximate to the center of the solder pad, releasing the solder balls, and reflowing assembly comprising the substrate, the solder balls, the solder paste, and solder particles in a reflow oven.

### RELATED APPLICATION

This application claims priority to U.S. Provisional Application Ser. No. 60/732,503, filed Nov. 1, 2005, entitled “METHOD AND APPARATUS FOR ATTACHING SOLDER BALLS TO SUBSTRATE”.

### FIELD OF THE INVENTION

The present invention relates generally to solder balls on substrates and more particularly to an improved system and method for attaching solder balls to substrates utilizing solder paste with distributed solder particles.

### BACKGROUND OF THE INVENTION

Packaged microelectronic memory devices, for example, are used in laptop computers, PDAs, scanners, cell phones, and the like. One approach used today is flip chip interconnect technology for electrically connecting the silicon die directly to the package carrier. The package carrier, either a substrate or leadframe, provides the connection from the silicon die to the exterior of the package. In standard packaging, the interconnection between the silicon die and the carrier is typically made using wire. The silicon die is attached to the carrier face up with a wire bonded first to the silicon die, and then bonded to the carrier. In contrast, the interconnection between the silicon die and carrier in flip chip packaging is made through first level solder joints utilizing conductive “bumps” to connect the silicon die and the substrate. Solder balls are typically employed to create a second level solder joint between the substrate BGA (ball grid array) and the printed circuit board, for example. The silicon die is then “flipped over” and placed face down, with the reflowed solder bumps connecting to the carrier directly. The solder bumps are typically configured in an array or pattern so that the individual solder bumps make contact with a corresponding bump pad, for example. Flip chip devices with solder bump connections generally have lower profiles, higher “pin” counts, higher signal density, reduced signal inductance, reduced power/ground inductance, for example than conventional chip packages utilizing lead frame technology.

Flip chip devices are typically mounted to circuit boards using surface mount techniques. Typically solder paste it is deposited on the circuit board contacts, for example and solder balls are pressed into the solder paste adhering to the contacts. With the flip chip device and the circuit board pressed together, the solder balls are surrounded by solder paste and either are moved proximate or are moved adjacent to the circuit board contacts. The chip device/circuit board assembly is then heated in a reflow oven, for example, so that the solder reflows and electromechanically connects the reflowed solder to the contacts.

A typical concern with surface mounting flip chip packages to circuit boards is that electrical shorts can occur if the solder from adjacent contacts reflow together. This shorting problem arises and is difficult to detect during the manufacturing process. In addition, conductive solder paste on a circuit board can create a short that renders the assembled flip chip device and/or circuit board inoperable. There is a greater likelihood of shorts occurring in these high density devices with high density grid patterns, because the spacing between adjacent contacts is very tight.

The electrical short is most easily detected after the assembly has been manufactured, and the problem often arises after the manufacturer has sold the electronic device. There are numerous problems associated with detecting shorting issues after sale of the device. For example, these devices often go into much larger electronic packages or devices, and therefore when a component fails the entire product has to be returned. Even greater problems can result in lost future revenues with customers and the perception of poor quality control by the consumer.

In addition, in some instances solder balls instead of shorting can be missing all together. The paste at times is not strong enough to hold the solder balls in position. The use of solder flux alone to hold the solder balls is not effective in preventing the balls from shifting on the substrate, especially when the substrate is warped.

Currently, standards are being developed and established for bump sizes, pitches, bump array layout, and general trends in the industry. These trends are driving smaller bump geometries with tighter bump pitches. Current bump pitches for most flip chip devices and CSPs (chip scale packaging), for example are further being decreased as well as bump pitches. This trend of reduced bump size and bump pitch poses new challenges for testing and burn-in of flip chip, CSP and other chip scale ball grid array packages (CSBGA).

In addition the substrate warpage is very difficult to control or eliminate during substrate and package assembly processes, due to critical thermal excursions, mechanical stress loadings, and stress dissipation capabilities of the package materials, and significant CTE mismatches across different materials comprising the flip chip package. Therefore a method is needed to properly allow for CTE mismatches and solder ball alignment during flip chip package assembly processing.

Therefore in flip chip technology and other applications utilizing solder balls there remains a need for properly aligning, retaining the solder ball when utilizing reflow technologies to ensure high quality, high yields and the like.

### SUMMARY OF THE INVENTION

The present invention is directed to an apparatus and method for attaching solder balls to a substrate or a similar device. The invention provides the utilization of solder paste with embedded solder particles in order to hold the solder ball on the SOP (solder over pad) pad, instead of solder flux alone.

According to one aspect of the invention, one method of applying the solder paste with distributed solder particles to the solder ball and the substrate solder pad comprises applying a solder paste with solder particles to the SOP pads utilizing a screening process. According to yet another aspect of the invention, another method of applying the solder paste to the solder balls is by dipping the solder balls into a layer of solder paste with distributed solder particles. The solder paste and solder particles are approximately uniformly dispersed throughout the paste. Another aspect of the invention is that the solder paste with distributed solder particles stabilize the solder balls so that when the substrate with solder balls is moved, prior to reflow, the ball do not move significantly or fall off the substrate, thus increasing yields over current technology.

According to yet another aspect of the invention, by attaching the solder balls to the SOP pads, with intervening solder paste with solder particles, when the solder balls reflow they do not short together, again increasing yields above current levels. This is because the solder balls are kept at a proper distance from each other which prevents the solder from one ball coming into contact with the solder from another ball.

According to yet another aspect of the present invention, another method of applying solder paste with solder particles by dipping allows up to 100% ball attach yields for solder ball systems even when there is significant BGA SOP pad metallization height differences across the substrate BGA footprint, and the substrate/package warping can not be reduced or eliminated. Substrate/package warpage is very commonly seen on large body size organic substrates before, during, and after package assembly.

To the accomplishment of the foregoing and related ends, the invention comprises the features hereinafter fully described and particularly pointed out in the claims. The following description and the annexed drawings set forth in detail certain illustrative aspects of the invention. These aspects are indicative, however, of but a few of the various ways in which the principles of the invention may be employed. Other objects, advantages and novel features of the invention will become apparent from the following detailed description of the invention when considered in conjunction with the drawings.

### BRIEF DESCRIPTION OF THE DRAWINGS

FIG. 1 is a side view illustrating a typical substrate with solder mounting pads according to one aspect of the present invention;

FIG. 2 is a side view of the substrate with solder mounting pads, shown in FIG. 1, where the method utilizes a screen or mask to apply solder paste containing particles to the solder pads according to an aspect of the invention;

FIG. 3 is a side view of the substrate, shown in FIG. 2, with solder paste and particles evenly applied to the solder pads, in accordance with another aspect of the invention;

FIG. 4 is a side view illustrating solder balls being picked up and placed upon the solder paste attached to the solder pads according to yet another aspect of the present invention;

FIG. 5 is a side view, illustrating the substrate with attached solder balls after the substrate has gone through a reflow process according to one aspect of the present invention;

FIG. 6 is a side elevation view illustrating solder paste and solder particles being spread out approximately uniform on a plate according to yet another aspect of the present invention;

FIG. 7 is a side elevation view of solder balls within a solder bin being picked up by a vacuum tool, according to an aspect of the present invention;

FIG. 8 is a side elevation view of solder balls being dipped in the solder paste with solder particles, according to another aspect of the present invention;

FIG. 9 is a side view of the solder balls being lifted out of the solder paste with the solder ball ends being covered with the solder paste and solder particles, according to yet another aspect of the present invention;

FIG. 10 is a side view illustrating the solder balls being placed over the solder pads and then being released, so that the solder balls rest on the solder pads with solder paste and solder particles interspersed between them according to an aspect of the present invention;

FIG. 11 is a side view of the solder balls attached to the solder pads after the substrate has gone through a reflow oven, according to yet another aspect the present invention;

FIG. 12 is a methodology shown graphically, according to yet another aspect of the present invention;

FIG. 13 is another methodology illustrated graphically, according to another aspect of the present invention.

### DETAILED DESCRIPTION OF THE INVENTION

The present invention will now be described with reference to the drawings wherein like reference numerals are used to refer to like elements throughout. The present invention provides a method for attaching solder balls to a substrate. However, it will be appreciated that the invention may be advantageously employed in applications other than those illustrated and described herein. The drawings/figures are illustrations that are not drawn to scale.

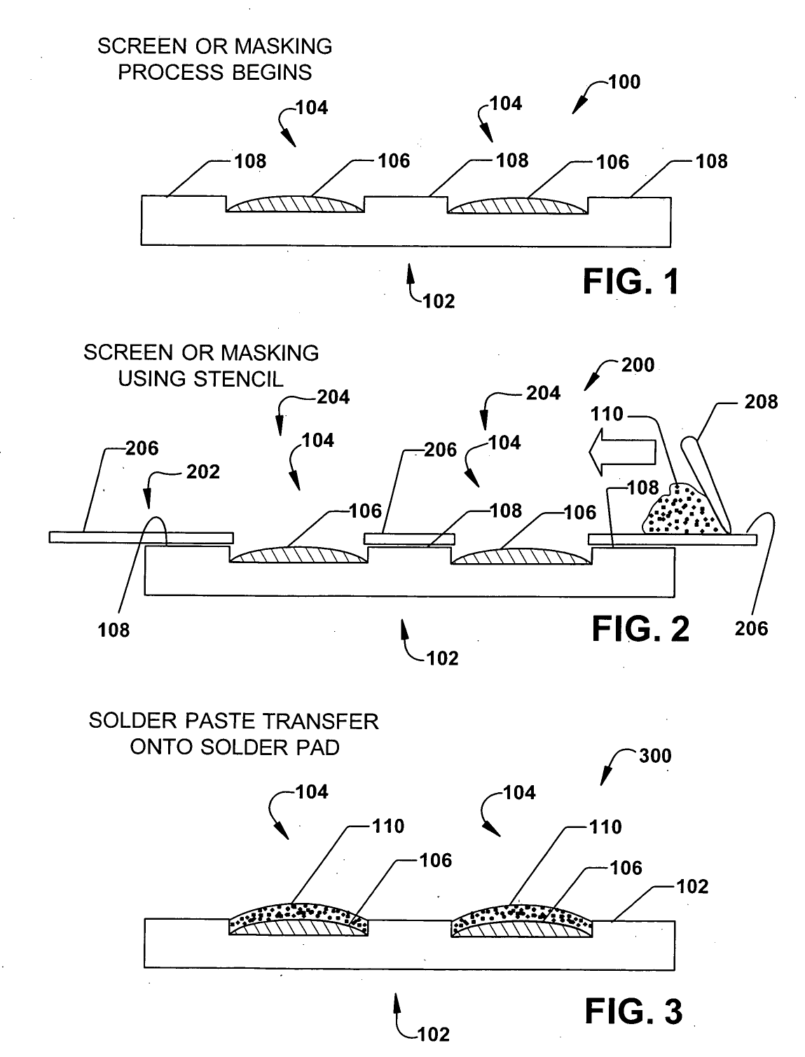

Referring now to the drawings, FIG. 1 through FIG. 5 illustrate a screen printing process that utilizes solder paste mixed with solder particles to position the solder ball accurately prior to a reflow process. In FIG. 1, a substrate 102 with SOP (solder on pad) pads 104 is illustrated. The SOP pads 104 are shown recessed into the substrate 102 where the upper surface of the convex pad face 106 is level with the upper surface of the substrate 108, for example. The SOP pads 104 can include at least one of the following materials, gold (Au), tin lead (SnPb), copper (Cu), Au/Ni/Cu, Ag/Cu, Au/Ni, and the like.

Referring now to FIG. 2, illustrated is the substrate 102 with a stencil or mask 202 placed on the substrate upper surface 108. The stencil or mask 202 has openings 204 which expose the various bonding pads 104 so that the bonding pads 104 can be coated with a solder paste containing solder particles 110. The solder paste with solder particles 110 is spread evenly over the solder pads 104 by utilizing a squeegee 208 that is pressed against the upper surface of the screen 206 and in this illustration, for example the squeegee 208 is pulled or pushed from right to left, as shown. When the squeegee 208 passes over the openings 204, the solder paste with solder particles 110 is forced into the openings 204 and the solder paste with solder particles 110 uniformly covers the convex surface 106 of the solder pads 104. Numerous passes of the squeegee 208 both from right to left and from left to right may be required in order to work the solder paste with solder particles 110 into the openings 204 in order to adequately coat the solder pads 104 within the substrate 102. The solder particles have an average size of 20 microns in any dimension and can be as large as 30 microns in any dimension.

FIG. 3 illustrates an exemplary screen printing process at 300, wherein the solder pad surface 106 is coated with a layer of solder paste with solder particles 110 and the screen mask has been subsequently removed. This can be one effective way to coat the solder pad surface 106 with a uniform layer of the solder paste with solder particles 110. The solder particles, in 300, can include at least one of the following materials, gold (Au), tin lead (SnPb), copper (Cu), Au/Ni/Cu, Ag/Cu, Au/Ni, and the like. At this point the substrate pads 104 are sufficiently coated with solder paste with solder particles 110 in order to receive solder balls (not shown).

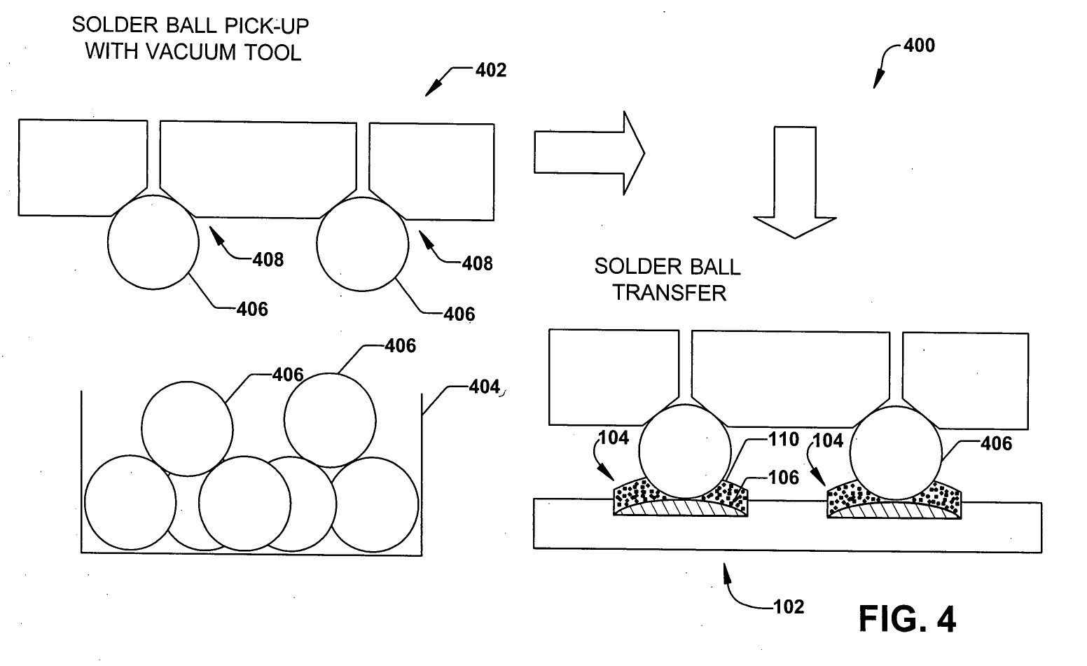

FIG. 4 illustrates another exemplary aspect of the present invention at 400. A vacuum tool 402 is positioned over a solder ball bin 404 and the vacuum tool 402 is used to pick up the solder balls 406 by applying suction at the end of the tool 408 in order to grasp the solder balls 406. The grasped solder balls 402 are then moved wherein they are positioned over the solder pads 106 and the solder paste with solder particles 110, with the solder balls 406 positioned at the center the pads 104 resting against the convex surface 106. Once the solder balls 406 are in the proper position and properly aligned, the vacuum tool 402 releases suction at 408, releasing the solder balls 406 and the vacuum tool 402 moves away from the solder balls 406. The solder balls 406 are held in place and in alignment by the solder paste and the particles 110 when the substrate is moved during subsequent processing. The solder particles are utilized in order to help prevent the solder balls 406 from rolling out of position when the substrate 102 and solder balls 406 are moved during various process steps. During the reflow process both the solder particles and the solder balls 406 reflow. The solder balls 406 and the solder particles can be the same solder material, for example or they can be made up of different solder materials or material combinations, depending upon the specific application. It should be appreciated by one of ordinary skill in the art that these techniques can be employed in any process that utilizes solder balls 406 to make an electrical connection.

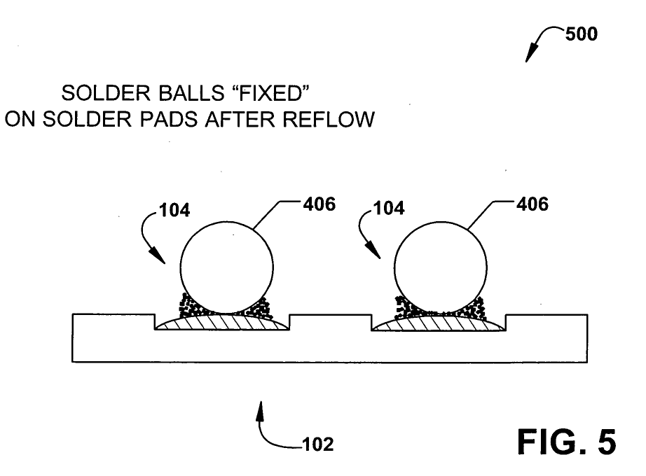

FIG. 5 illustrates yet another aspect of the invention at 500 in cross section. As seen in FIG. 5, the solder balls, 406 are aligned on top of the solder pads 104 so that the solder balls 406 are centered on top of and in contact with the solder pad surface 104. The solder particles within the solder paste 110 help to keep the solder balls properly aligned and centered so that when the substrate goes through the reflow oven, for example, the solder particles and solder balls 406 both reflow with the solder balls in proper alignment. The solder particles enclosed within a solder paste 110 can be made “smart” or capable of wetting only the surface area of the solder balls in contact with the substrate solder pad surface 106. At FIG. 5, the solder balls 406 are properly aligned and attached to the substrate solder pads 106 after a reflow process in a reflow oven, for example.

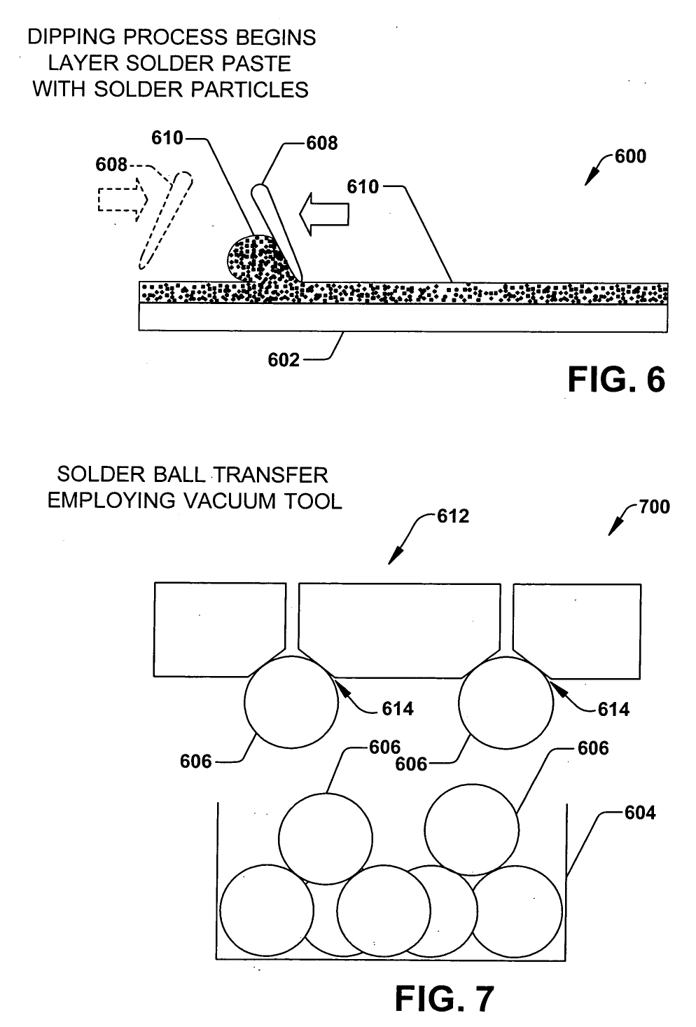

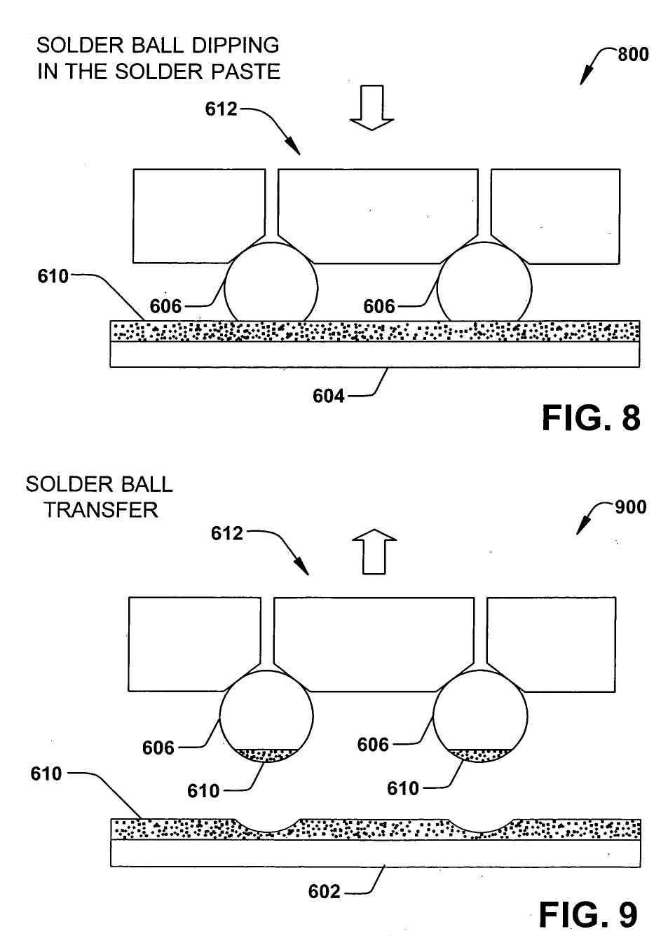

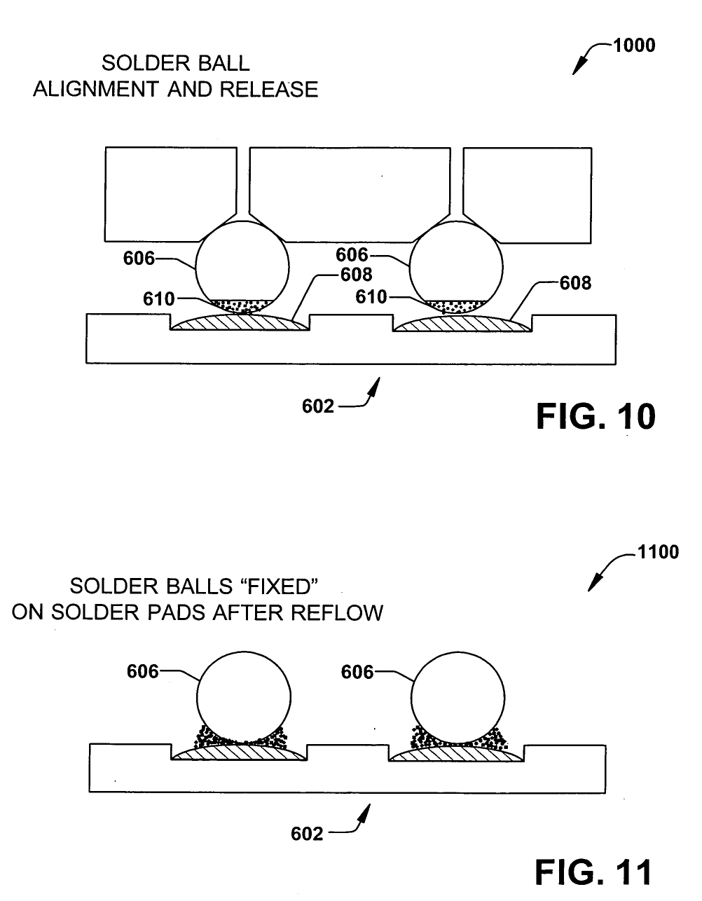

Referring now to FIG. 6, a solder ball dipping process begins and is illustrated at 600. In FIG. 6, solder paste with solder particles 610 is moved with a squeegee 608 along a plate 602 by a back-and-forth motion of the squeegee 608. The squeegee 608 as illustrated herein is moved left to right and right to left, while raising the squeegee 608 in each subsequent step, until the solder paste 610 has a uniform thickness and flatness of solder paste with embedded solder particles 610 developed on the flat plate 604. The solder particles are approximately distributed uniformly throughout the solder paste 610, as illustrated, for example. In FIG. 7, the solder balls 606 are picked up in a similar manner to FIG. 4 using a vacuum tool 608, for example. The solder balls 606 are dipped into the solder paste 610 so that the balls 606 pick up an desired amount of solder paste and solder particles 610, as illustrated in FIG. 8. The solder paste with solder particles 610 is highly viscous, and therefore sticks to the outer surface of the solder balls 606. In FIG. 9 the solder balls 606 are then lifted out of the solder paste 610 and placed over and in direct contact with the solder pads 608 on the substrate 602, in FIG. 10. This allows the solder balls 606 to be held, positioned and aligned properly over the solder pads 608 on the substrate 602. The substrate 602, the solder pads 608, the solder paste and solder particles 610 and the solder balls 606 are then processed through a reflow oven, for example in FIG. 11. The solder particles and the solder balls 606 can then be reflowed, for example in a reflow oven. As the solder balls 406 and solder particles reflow the solder balls 406 are held in the proper position and alignment.

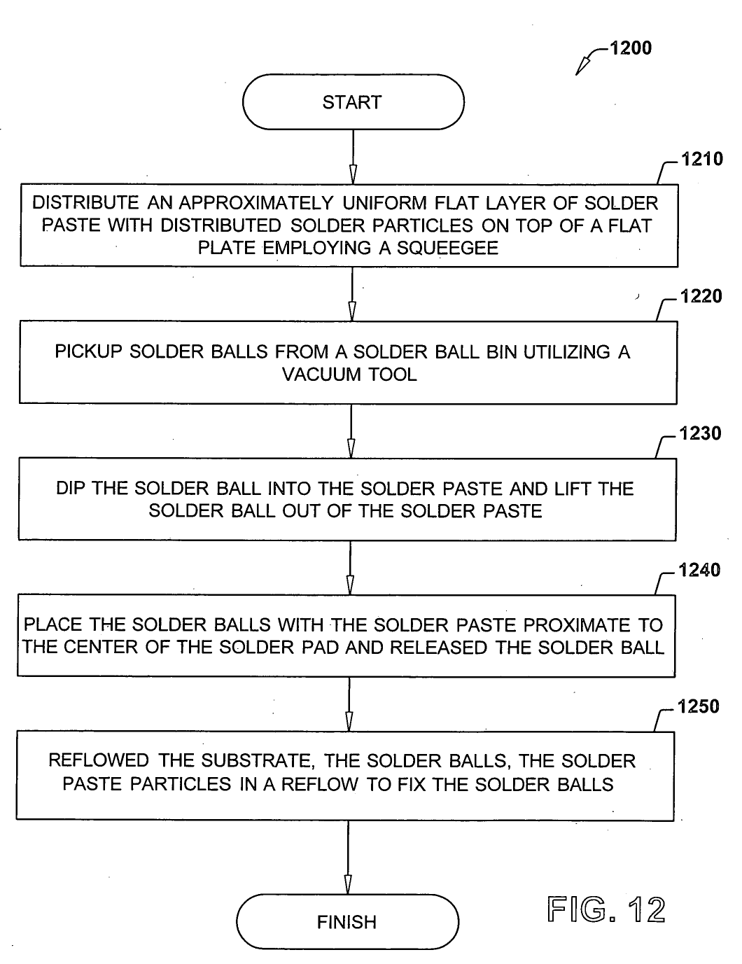

An exemplary method 1200 is hereinafter illustrated and described with respect to FIG. 12. Although the exemplary method 1200 is illustrated and described below as a series of acts or events, it will be appreciated that the present invention is not limited by the illustrated ordering of such acts or events. For example, some acts may occur in different orders and/or concurrently with other acts or events apart from those illustrated and/or described herein, in accordance with the invention. In addition, not all illustrated steps may be required to implement a methodology in accordance with the present invention. Further, the methods according to the present invention may be implemented in association with the fabrication and/or processing of flash memory devices illustrated and described herein as well as in association with other structures and devices not illustrated. Beginning with a flat plate at 1210, an approximately uniform flat layer of solder paste with embedded solder particles is distributed over the flat plate. The solder paste with distributed solder particles at 1210 can be distributed with a squeegee, by moving the squeegee back and forth above the plate. However, it should be apparent to one of ordinary skill in the art that the solder paste with solder particles can be distributed using spraying techniques, spinning techniques, brushing techniques, and the like.

At 1220, solder balls are picked from a solder ball bin utilizing a vacuum tool, for example. It should be apparent to one of ordinary skill in the art that the solder balls could be moved utilizing pinchers, pick and place devices, magnetic pickups, and the like. The solder balls are dipped into the solder paste and removed, at 1230. The viscosity of the solder paste allows the paste to adhere to the bottom of the solder ball. At 1240, the solder balls are placed proximate to the center of the solder pad and released so that the solder ball is in contact with the solder pad. The substrate, the solder balls and the solder paste with solder particles is run through a reflow oven in order to fix the solder balls to the substrate, at 1250, wherein the dipping process ends.

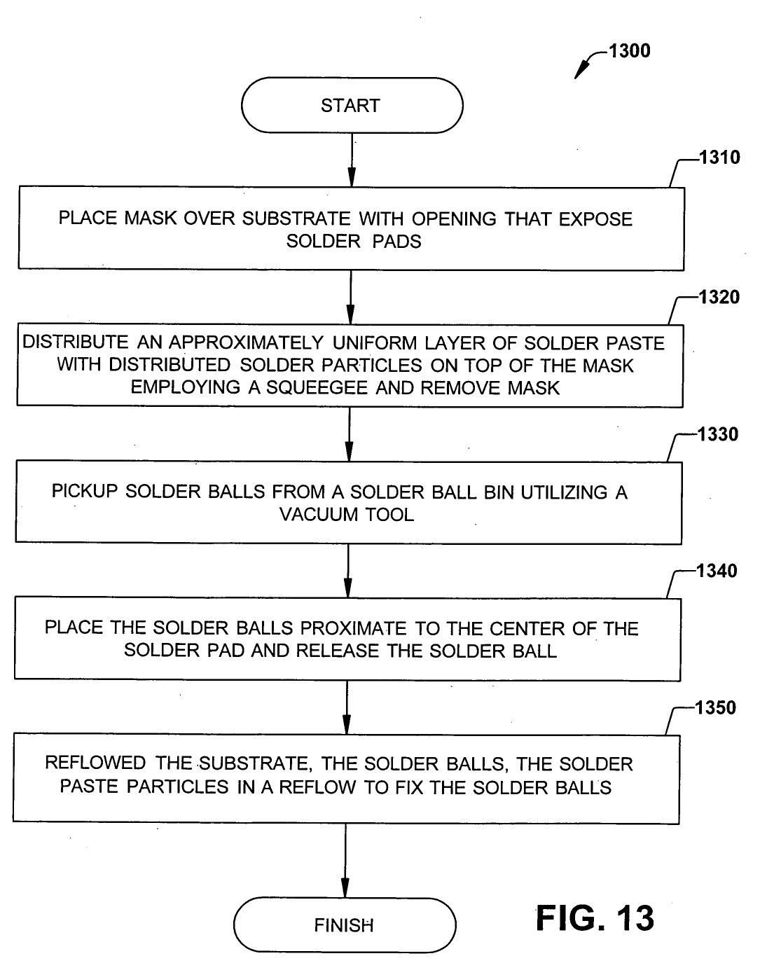

Yet another exemplary method 1300 is illustrated and described with respect to FIG. 13, wherein a screening or masking process is used to attach solder balls to a substrate. Although the exemplary method 1300 is illustrated and described below as a series of acts or events, it will be appreciated that the present invention is not limited by the illustrated ordering of such acts or events. For example, some acts may occur in different orders and/or concurrently with other acts or events apart from those illustrated and/or described herein, in accordance with the invention. In addition, not all illustrated steps may be required to implement a methodology in accordance with the present invention. Further, the methods according to the present invention may be implemented in association with the fabrication and/or processing of flash memory devices illustrated and described herein as well as in association with other structures and devices not illustrated.

Beginning with a substrate and a mask at 1310, the mask is placed over the substrate so that the openings of the mask expose various solder pads. At 1320, a uniform layer of solder paste with distributed solder particles is spread in a uniform fashion over the top of the mask employing a squeegee, for example. Once the solder paste is properly distributed on the solder pads, the mask is removed. However, it should be apparent to one of ordinary skill in the art that the solder paste can be distributed using spraying techniques, brushing techniques, roller techniques, and the like.

At 1330, solder balls are picked from a solder ball bin utilizing a vacuum tool, for example. It should be apparent to one of ordinary skill in the art that the solder balls could be moved employing pick and place devices, magnetic pickups, robotics, and the like. At 1340, the solder balls are placed near the center of the solder pad and released so that the solder ball is in contact with the solder pad that is at least partially coated with the solder paste. The substrate with attached solder balls, resting on the solder paste with solder particles is processed through a reflow oven to fix the solder balls to the substrate, at 1350, wherein the screening and/or masking process ends.

Although the invention has been shown and described with respect to a certain applications and implementations, it will be appreciated that equivalent alterations and modifications will occur to others skilled in the art upon the reading and understanding of this specification and the annexed drawings. In particular regard to the various functions performed by the above described components (assemblies, devices, circuits, systems, etc.), the terms (including a reference to a “means”) used to describe such components are intended to correspond, unless otherwise indicated, to any component which performs the specified function of the described component (i.e., that is functionally equivalent), even though not structurally equivalent to the disclosed structure, which performs the function in the herein illustrated exemplary implementations of the invention.

In addition, while a particular feature of the invention may have been disclosed with respect to only one of several implementations, such feature may be combined with one or more other features of the other implementations as may be desired and advantageous for any given or particular application. Furthermore, to the extent that the terms “includes”, “including”, “has”, “having”, and variants thereof are used in either the detailed description or the claims, these terms are intended to be inclusive in a manner similar to the term “comprising”.

What is claimed is:

1. A method for attaching solder balls to solder pads on a substrate, comprising;
coating at least a portion of the solder ball or the solder pad with solder paste having distributed solder particles;
placing the solder balls on the solder pad; and
reflowing the substrate, the solder balls, the solder paste and the solder particles.

2. The method of claim 1, wherein the solder pads comprise at least one of the following: gold (Au), tin lead (SnPb), copper (Cu), Au/Ni/Cu, Ag/Cu, and Au/Ni.

3. The method of claim 1, wherein the solder balls comprise at least one of the following: PbSnAg, SnAgCu, SnPb, SnAg, and Au.

4. The method of claim 1, wherein the solder particles comprise at least one of the following: gold (Au), tin lead (SnPb), copper (Cu), Au/Ni/Cu, Ag/Cu and Au/Ni.

5. The method of claim 1, wherein the solder particles are approximately 30 microns or less, when measuring any dimension of the particle.

6. The method of claim 1, wherein the solder particles are approximately spherical in shape.

7. A method for attaching solder balls to solder pads on a circuit board, comprising;
distributing an approximately uniform flat layer of solder paste with dispersed solder particles on top of a flat plate employing a squeegee;
picking up the solder balls from a solder ball bin utilizing a vacuum tool;
dipping the solder balls into the solder paste;
lifting the solder balls out of the solder paste;
placing the solder balls with the solder paste proximate to the center of the solder pad;
releasing the solder balls; and
reflowing the substrate, the solder paste with dispersed solder particles and the solder balls, in a reflow oven.

8. The method of claim 7, wherein the solder particles are about 30 microns or less, in any dimension of the solder particle.

9. The method of claim 7, wherein the solder pads comprise at least one of the following: gold (Au), tin lead (SnPb), copper (Cu), Au/Ni/Cu, Ag/Cu, and Au/Ni.

10. The method of claim 7, wherein the solder balls comprise at least one of the following: PbSnAg, SnAgCu, SnPb, SnAg, and Au.

11. The method of claim 7, wherein the solder particles comprise at least one of the following: gold (Au), tin lead (SnPb), copper (Cu), Au/Ni/Cu, Ag/Cu and Au/Ni.

12. The method of claim 7, wherein the pickup tool comprises at least one of the following: a vacuum tool, a jawed tool, and a magnetic tool.

13. The method of claim 7, wherein the solder paste with dispersed solder particles can be placed on the flat plate utilizing at least one of the following: painting, spraying, squeeging, dipping, and spinning the plate.

14. A method for attaching solder balls to solder pads on a substrate, comprising;
placing a mask over the substrate with mask openings exposing the solder pads;
distributing an approximately uniform layer of solder paste with distributed solder particles on the solder pads employing a squeegee to spread the solder paste uniformly over the mask;
removing the mask; picking up the solder balls from a solder ball bin utilizing a pickup tool;
placing the solder balls proximate to the center of the solder pad;
releasing the solder balls; and
reflowing the substrate paste and distributed solder particles, and the solder balls.

15. The method of claim 14, wherein the pickup tool comprises a grasping device, to grasper device, and magnetic device.

16. The method of claim 14, wherein the solder pads comprise at least one of the following: gold (Au), tin lead (SnPb), copper (Cu), Au/Ni/Cu, Ag/Cu, and Au/Ni.

17. The method of claim 14, wherein the solder balls comprise at least one of the following: PbSnAg, SnAgCu, SnPb, SnAg, and Au.

18. The method of claim 14, wherein the solder particles comprise at least one of the following: gold (Au), tin lead (SnPb), copper (Cu), Au/Ni/Cu, Ag/Cu and Au/Ni.

19. The method of claim 14, wherein the solder paste with distributed solder particles can be placed on the mask utilizing at least one of the following: painting, spraying, squeeging, dipping, and spinning the substrate.

20. The method of claim 14, wherein the solder particles are about 30 microns or less, in any dimension of the solder particle.

21. A solder ball attachment system for attaching the solder balls to a substrate, the solder ball attachment system comprising:
solder pads attached to the substrate;
a solder paste with solder particles contacting at least a portion of a solder pad or the solder ball or both;
wherein the balls are placed in contact with the solder pads; and the solder particles are reflowed to attach the solder balls to the solder pads.

22. The solder ball attachment system of claim 21, wherein a reflow is executed in a chamber comprising thermal, vibration, chemical, and magnetic.

23. The solder ball attachment system of claim 21, wherein the solder pads comprise at least one of the following: gold (Ag), tin lead (SnPb), copper (Cu), Au/Ni/Cu, Ag/Cu, and Au/Ni.

24. The solder ball attachment system of claim 21, wherein the solder balls comprise at least one of the following: PbSnAg, SnAgCu, SnPb, SnAg, and Au.

25. The solder ball attachment system of claim 21, wherein the solder particles comprise at least one of the following: gold (Ag), tin lead (SnPb), copper (Cu), Au/Ni/Cu, Ag/Cu and Au/Ni.

26. The solder ball attachment system of claim 21, wherein the solder particles are approximately 30 micron in size or less.
